(19) United States
(12) Patent Application Publication
(10) Pub. No.: US 2003/0235076 A1
(43) Pub. Date: Dec. 25, 2003

(54) Multistate NROM having a storage density much greater than 1 Bit per 1F2

(75) Inventor: Leonard Forbes, Corvallis, OR (US)

Correspondence Address: Schwegman, Lundberg, Woessner & Kluth, P.A., Attn: Edward J. Brooks, TTT, P.O. Box 2938, Minneapolis, MN, 55402, US

(73) Assignee: Micron Technology, Inc.

(21) Appl. No.: 10/177,211

(22) Filed: Jun. 21, 2002

(51) Int. Cl. G11C 16/04

(52) U.S. Cl. 365/185.03; 365/185.05; 365/185.18

(57) ABSTRACT

Structures and methods for vertical multistate cell. The cell includes a vertical metal oxide semiconductor field effect transistor (MOSFET) extending outwardly from a substrate, the MOSFET having a first source/drain region, a second source/drain region, a channel region between the first and the second source/drain regions, and a gate separated from the channel region by a gate insulator. A sourceline is formed in a trench adjacent to the vertical MOSFET, wherein the first source/drain region is coupled to the sourceline. A transmission line is coupled to the second source/drain region. The can be programmed MOSFET to have one of a number of charge levels trapped in the gate insulator adjacent to the first source/drain region such that the channel region has a first voltage threshold region (Vt1) and a second voltage threshold region (Vt2) and such that the programmed MOSFET operates at reduced drain source current.

### CROSS REFERENCE TO RELATED APPLICATIONS

This application is related to the following co-pending, commonly assigned U.S. patent applications: “Write Once Read Only Memory Employing Charge Trapping in Insulators,” attorney docket no. 1303.052U.S. 1, Ser. No. ______, “Write Once Read Only Memory Employing Floating Gates,” attorney docket no. 1303.051U.S.1, Ser. No. ______, “Nanocrystal Write Once Read Only Memory for Archival Storage,” attorney docket no. 1303.054U.S.1, Ser. No. ______, “Write Once Read Only Memory with Large Work Function Floating Gates,” attorney docket no. 1303.055U.S.1, Ser. No. ______, “Ferroelectric Write Once Read Only Memory for Archival Storage,” attorney docket no. 1303.058U.S.1, Ser. No. ______, and “Vertical NROM Having a Storage Density of 1 Bit per 1F²,” attorney docket no. 1303.057U.S.1, Ser. No. ______, which are filed on even date herewith and each of which disclosure is herein incorporated by reference.

### FIELD OF THE INVENTION

The present invention relates generally to semiconductor integrated circuits and, more particularly, to multistate NROM having a storage density much greater than one bit for each 1.0 lithographic feature squared (1F²) unit area.

### BACKGROUND OF THE INVENTION

Many electronic products need various amounts of memory to store information, e.g. data. One common type of high speed, low cost memory includes dynamic random access memory (DRAM) comprised of individual DRAM cells arranged in arrays. DRAM cells include an access transistor, e.g a metal oxide semiconducting field effect transistor (MOSFET), coupled to a capacitor cell. With successive generations of DRAM chips, an emphasis continues to be placed on increasing array density and maximizing chip real estate while minimizing the cost of manufacture. It is further desirable to increase array density with little or no modification of the DRAM optimized process flow.

A requirement exists for memory devices which need only be programmed a limited number of times, as for instance to function as an electronic film in a camera. If the memory arrays have a very high density then they can store a large number of very high resolution images in a digital camera. If the memory is inexpensive then it can for instance replace the light sensitive films which are used to store images in conventional cameras.

Thus, there is a need for improved DRAM technology compatible multistate NROM having a storage density of much greater than one bit per for each 1.0 lithographic feature squared (1F²) unit area. It is desirable that such a multistate NROM be fabricated on a DRAM chip with little or no modification of the DRAM process flow. It is further desirable that such a multistate NROM operate with lower programming voltages than that used by conventional DRAM cells, yet still hold sufficient charge to withstand the effects of parasitic capacitances and noise due to circuit operation.

### SUMMARY OF THE INVENTION

The above mentioned problems for creating DRAM technology compatible multistate cells as well as other problems are addressed by the present invention and will be understood by reading and studying the following specification. This disclosure teaches structures and methods using MOSFET devices as multistate memory cells in a DRAM integrated circuit. The structures and methods use the existing process sequence for MOSFET's in DRAM technology.

In particular, an illustrative embodiment of the present invention includes a vertical metal oxide semiconductor field effect transistor (MOSFET) extending outwardly from a substrate, the MOSFET having a first source/drain region, a second source/drain region, a channel region between the first and the second source/drain regions, and a gate separated from the channel region by a gate insulator. A sourceline is formed in a trench adjacent to the vertical MOSFET, wherein the first source/drain region is coupled to the sourceline. A transmission line is coupled to the second source/drain region. The can be programmed MOSFET to have one of a number of charge levels trapped in the gate insulator adjacent to the first source/drain region such that the channel region has a first voltage threshold region (Vt1) and a second voltage threshold region (Vt2) and such that the programmed MOSFET operates at reduced drain source current.

These and other embodiments, aspects, advantages, and features of the present invention will be set forth in part in the description which follows, and in part will become apparent to those skilled in the art by reference to the following description of the invention and referenced drawings or by practice of the invention. The aspects, advantages, and features of the invention are realized and attained by means of the instrumentalities, procedures, and combinations particularly pointed out in the appended claims.

### BRIEF DESCRIPTION OF THE DRAWINGS

FIG. 1A is a block diagram of a metal oxide semiconductor field effect transistor (MOSFET) in a substrate according to the teachings of the prior art.

FIG. 1B illustrates the MOSFET of FIG. 1A operated in the forward direction showing some degree of device degradation due to electrons being trapped in the gate oxide near the drain region over gradual use.

FIG. 1C is a graph showing the square root of the current signal (Ids) taken at the drain region of the conventional MOSFET versus the voltage potential (VGS) established between the gate and the source region.

FIG. 2A is a diagram of a programmed MOSFET which can be used as a multistate cell according to the teachings of the present invention.

FIG. 2B is a diagram suitable for explaining the method by which the MOSFET of the multistate cell of the present invention can be programmed to achieve the embodiments of the present invention.

FIG. 2C is a graph plotting the current signal (Ids) detected at the drain region versus a voltage potential, or drain voltage, (VDS) set up between the drain region and the source region (Ids vs. VDS).

FIG. 3 illustrates a portion of a memory array according to the teachings of the present invention.

FIG. 4 illustrates an electrical equivalent circuit for the portion of the memory array shown in FIG. 3.

FIG. 5 is another electrical equivalent circuit useful in illustrating a read operation on the novel multistate cell according to the teachings of the present invention.

FIG. 6 illustrates a portion of a memory array according to the teachings of the present invention.

FIG. 7A, illustrates one embodiment of the gate insulator for the present invention having a number of layers, e.g. an ONO stack, where the layer closest to the channel includes an oxide layer, and a nitride layer is formed thereon.

FIG. 7B aids to further illustrate the conduction behavior of the novel multistate cell of the present invention.

FIG. 8A illustrates the operation and programming the novel multistate cell in the reverse direction.

FIG. 8B illustrates the now programmed multistate cell's operation in the forward direction and differential read occurring in this differential cell embodiment, e.g. 2 transistors in each cell.

FIG. 9 illustrates a memory device according to the teachings of the present invention.

FIG. 10 is a block diagram of an electrical system, or processor-based system, utilizing a multistate cell constructed in accordance with the present invention.

### DESCRIPTION OF THE PREFERRED EMBODIMENTS

In the following detailed description of the invention, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention.

The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors, and the term insulator is defined to include any material that is less electrically conductive than the materials referred to as conductors. The following detailed description is, therefore, not to be taken in a limiting sense, and the scope of the present invention is defined only by the appended claims, along with the full scope of equivalents to which such claims are entitled.

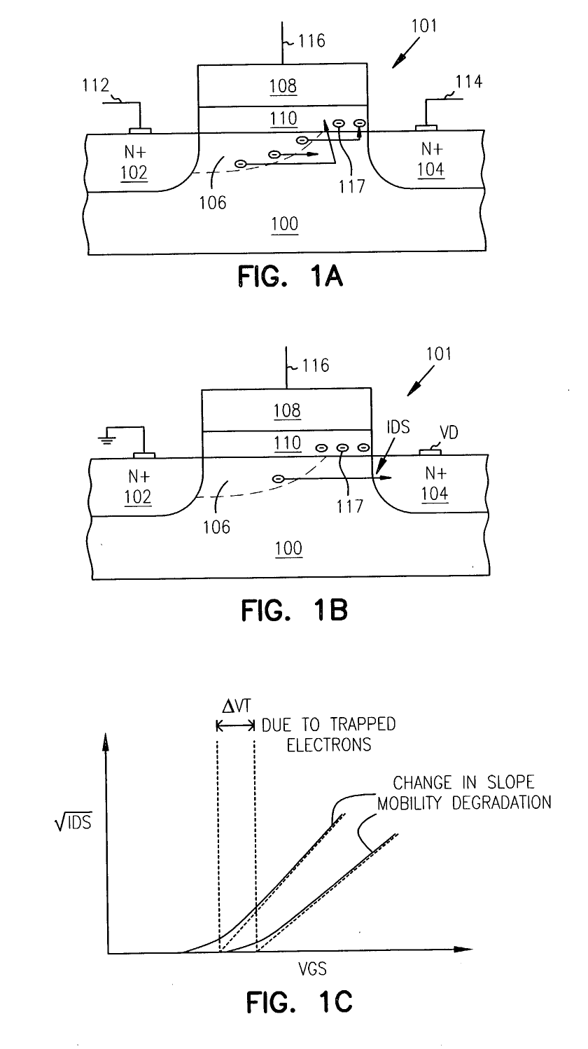

FIG. 1A is useful in illustrating the conventional operation of a MOSFET such as can be used in a DRAM array. FIG. 1A illustrates the normal hot electron injection and degradation of devices operated in the forward direction. As is explained below, since the electrons are trapped near the drain they are not very effective in changing the device characteristics.

FIG. 1A is a block diagram of a metal oxide semiconductor field effect transistor (MOSFET) 101 in a substrate 100. The MOSFET 101 includes a source region 102, a drain region 104, a channel region 106 in the substrate 100 between the source region 102 and the drain region 104. A gate 108 is separated from the channel region 108 by a gate oxide 110. A sourceline 112 is coupled to the source region 102. A bitline 114 is coupled to the drain region 104. A wordline 116 is coupled to the gate 108.

In conventional operation, a drain to source voltage potential (Vds) is set up between the drain region 104 and the source region 102. A voltage potential is then applied to the gate 108 via a wordline 116. Once the voltage potential applied to the gate 108 surpasses the characteristic voltage threshold (Vt) of the MOSFET a channel 106 forms in the substrate 100 between the drain region 104 and the source region 102. Formation of the channel 106 permits conduction between the drain region 104 and the source region 102, and a current signal (Ids) can be detected at the drain region 104.

In operation of the conventional MOSFET of FIG. 1A, some degree of device degradation does gradually occur for MOSFETs operated in the forward direction by electrons 117 becoming trapped in the gate oxide 110 near the drain region 104. This effect is illustrated in FIG. 1B. However, since the electrons 117 are trapped near the drain region 104 they are not very effective in changing the MOSFET characteristics.

FIG. 1C illustrates this point. FIG. 1C is a graph showing the square root of the current signal (Ids) taken at the drain region versus the voltage potential (VGS) established between the gate 108 and the source region 102. The change in the slope of the plot of \sqrt{Ids} versus VGS represents the change in the charge carrier mobility in the channel 106.

In FIG. 1C, ΔVT represents the minimal change in the MOSFET's threshold voltage resulting from electrons gradually being trapped in the gate oxide 110 near the drain region 104, under normal operation, due to device degradation. This results in a fixed trapped charge in the gate oxide 110 near the drain region 104. Slope 1 represents the charge carrier mobility in the channel 106 for FIG. 1A having no electrons trapped in the gate oxide 110. Slope 2 represents the charge mobility in the channel 106 for the conventional MOSFET of FIG. 1B having electrons 117 trapped in the gate oxide 110 near the drain region 104. As shown by a comparison of slope 1 and slope 2 in FIG. 1C, the electrons 117 trapped in the gate oxide 110 near the drain region 104 of the conventional MOSFET do not significantly change the charge mobility in the channel 106.

There are two components to the effects of stress and hot electron injection. One component includes a threshold voltage shift due to the trapped electrons and a second component includes mobility degradation due to additional scattering of carrier electrons caused by this trapped charge and additional surface states. When a conventional MOSFET degrades, or is “stressed,” over operation in the forward direction, electrons do gradually get injected and become trapped in the gate oxide near the drain. In this portion of the conventional MOSFET there is virtually no channel underneath the gate oxide. Thus the trapped charge modulates the threshold voltage and charge mobility only slightly.

The inventors have previously described programmable memory devices and functions based on the reverse stressing of MOSFET's in a conventional CMOS process and technology in order to form programmable address decode and correction. (See generally, L. Forbes, W. P. Noble and E. H. Cloud, “MOSFET technology for programmable address decode and correction,” application Ser. No. 09/383804). That disclosure, however, did not describe multistate memory cell solutions, but rather address decode and correction issues.

According to the teachings of the present invention, normal MOSFETs can be programmed by operation in the reverse direction and utilizing avalanche hot electron injection to trap electrons in the gate oxide of the MOSFET. When the programmed MOSFET is subsequently operated in the forward direction the electrons trapped in the oxide are near the source and cause the channel to have two different threshold voltage regions. The novel programmed MOSFETs of the present invention conduct significantly less current than conventional MOSFETs, particularly at low drain voltages. These electrons will remain trapped in the gate oxide unless negative gate voltages are applied. The electrons will not be removed from the gate oxide when positive or zero gate voltages are applied. Erasure can be accomplished by applying negative gate voltages and/or increasing the temperature with negative gate bias applied to cause the trapped electrons to be re-emitted back into the silicon channel of the MOSFET. (See generally, L. Forbes, E. Sun, R. Alders and J. Moll, “Field induced re-emission of electrons trapped in SiO₂,” IEEE Trans. Electron Device, vol. ED-26, no. 11, pp. 1816-1818 (November 1979); S. S. B. Or, N. Hwang, and L. Forbes, “Tunneling and Thermal emission from a distribution of deep traps in SiO₂,” IEEE Trans. on Electron Devices, vol. 40, no. 6, pp. 1100-1103 (June 1993); S. A. Abbas and R. C. Dockerty, “N-channel IGFET design limitations due to hot electron trapping,” IEEE Int. Electron Devices Mtg., Washington D.C., December 1975, pp. 35-38).

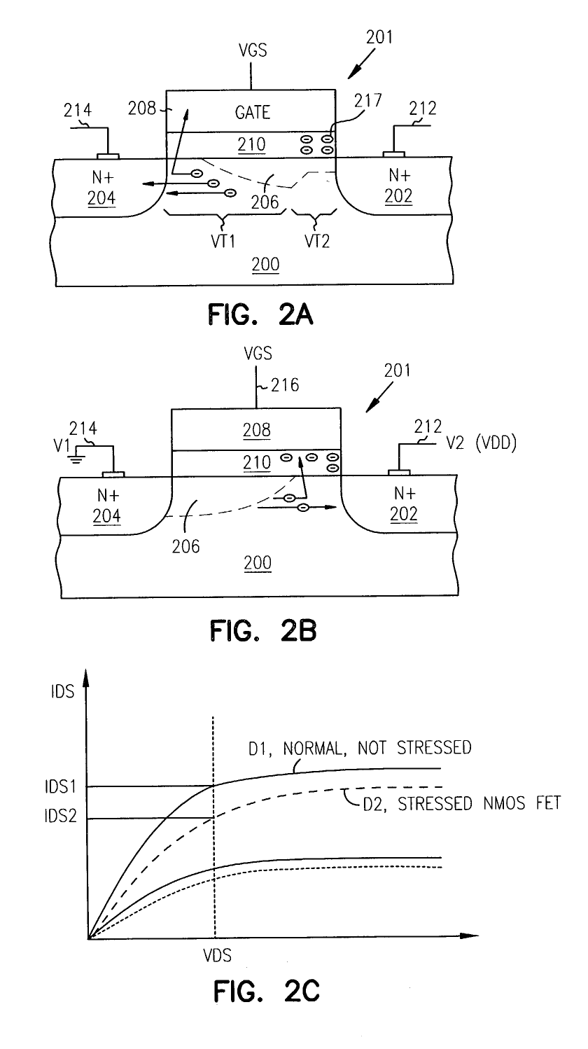

FIGS. 2A-2C illustrate are useful in illustrating the present invention in which a much larger change in device characteristics is obtained by programming the device in the reverse direction and subsequently reading the device by operating it in the forward direction.

FIG. 2A is a diagram of a programmed MOSFET which can be used as a multistate cell according to the teachings of the present invention. As shown in FIG. 2A the multistate cell 201 includes a MOSFET in a substrate 200 which has a first source/drain region 202, a second source/drain region 204, and a channel region 206 between the first and second source/drain regions, 202 and 204. In one embodiment, the first source/drain region 202 includes a source region 202 for the MOSFET and the second source/drain region 204 includes a drain region 204 for the MOSFET. FIG. 2A further illustrates a gate 208 separated from the channel region 206 by a gate oxide 210. A first transmission line 212 is coupled to the first source/drain region 202 and a second transmission line 214 is coupled to the second source/drain region 204. In one embodiment, the first transmission line includes a sourceline 212 and the second transmission line includes a bit line 214.

As stated above, multistate cell 201 is comprised of a programmed MOSFET. This programmed MOSFET has a charge 217 trapped in the gate oxide 210 adjacent to the first source/drain region 202 such that the channel region 206 has a first voltage threshold region (Vt1) and a second voltage threshold region (Vt2) in the channel 206. In one embodiment, the charge 217 trapped in the gate oxide 210 adjacent to the first source/drain region 202 includes a trapped electron charge 217. According to the teachings of the present invention and as described in more detail below, the multistate cell can be programmed to have one of a number of charge levels trapped in the gate insulator adjacent to the first source/drain region 202 such that the channel region 206 will have a first voltage threshold region (Vt1) and a second voltage threshold region (Vt2) and such that the programmed multistate cell operates at reduced drain source current.

FIG. 2A illustrates the Vt2 in the channel 206 is adjacent the first source/drain region 202 and that the Vt1 in the channel 206 is adjacent the second source/drain region 204. According to the teachings of the present invention, Vt2 has a higher voltage threshold than Vt1 due to the charge 217 trapped in the gate oxide 217 adjacent to the first source/drain region 202. Multiple bits can be stored on the multistate cell 201.

FIG. 2B is a diagram suitable for explaining the method by which the MOSFET of the multistate cell 201 of the present invention can be programmed to achieve the embodiments of the present invention. As shown in FIG. 2B the method includes programming the MOSFET in a reverse direction. Programming the MOSFET in the reverse direction includes applying a first voltage potential V1 to a drain region 204 of the MOSFET. In one embodiment, applying a first voltage potential V1 to the drain region 204 of the MOSFET includes grounding the drain region 204 of the MOSFET as shown in FIG. 2B. A second voltage potential V2 is applied to a source region 202 of the MOSFET. In one embodiment, applying a second voltage potential V2 to the source region 202 includes applying a high positive voltage potential (VDD) to the source region 202 of the MOSFET, as shown in FIG. 2B. A gate potential VGS is applied to a gate 208 of the MOSFET. In one embodiment, the gate potential VGS includes a voltage potential which is less than the second voltage potential V2, but which is sufficient to establish conduction in the channel 206 of the MOSFET between the drain region 204 and the source region 202. As shown in FIG. 2B, applying the first, second and gate potentials (V1, V2, and VGS respectively) to the MOSFET creates a hot electron injection into a gate oxide 210 of the MOSFET adjacent to the source region 202. In other words, applying the first, second and gate potentials (V1, V2, and VGS respectively) provides enough energy to the charge carriers, e.g. electrons, being conducted across the channel 206 that, once the charge carriers are near the source region 202, a number of the charge carriers get excited into the gate oxide 210 adjacent to the source region 202. Here the charge carriers become trapped.

In one embodiment of the present invention, the method is continued by subsequently operating the MOSFET in the forward direction in its programmed state during a read operation. Accordingly, the read operation includes grounding the source region 202 and precharging the drain region a fractional voltage of VDD. If the device is addressed by a wordline coupled to the gate, then its conductivity will be determined by the presence or absence of stored charge in the gate insulator. That is, a gate potential can be applied to the gate 208 by a wordline 216 in an effort to form a conduction channel between the source and the drain regions as done with addressing and reading conventional DRAM cells.

However, now in its programmed state, the conduction channel 206 of the MOSFET will have a first voltage threshold region (Vt1) adjacent to the drain region 204 and a second voltage threshold region (Vt2) adjacent to the source region 202, as explained and described in detail in connection with FIG. 2A. According to the teachings of the present invention, the Vt2 has a greater voltage threshold than the Vt1 due to the hot electron injection 217 into a gate oxide 210 of the MOSFET adjacent to the source region 202.

FIG. 2C is a graph plotting a current signal (Ids) detected at the second source/drain region 204 versus a voltage potential, or drain voltage, (VDS) set up between the second source/drain region 204 and the first source/drain region 202 (Ids vs. VDS). In one embodiment, VDS represents the voltage potential set up between the drain region 204 and the source region 202. In FIG. 2C, the curve plotted as D1 represents the conduction behavior of a conventional MOSFET which is not programmed according to the teachings of the present invention. The curve D2 represents the conduction behavior of the programmed MOSFET, described above in connection with FIG. 2A, according to the teachings of the present invention. As shown in FIG. 2C, for a particular drain voltage, VDS, the current signal (IDS2) detected at the second source/drain region 204 for the programmed MOSFET (curve D2) is significantly lower than the current signal (IDS1) detected at the second source/drain region 204 for the conventional MOSFET which is not programmed according to the teachings of the present invention. Again, this is attributed to the fact that the channel 206 in the programmed MOSFET of the present invention has two voltage threshold regions and that the voltage threshold, Vt2, near the first source/drain region 202 has a higher voltage threshold than Vt1 near the second source/drain region due to the charge 217 trapped in the gate oxide 217 adjacent to the first source/drain region 202.

Some of these effects have recently been described for use in a different device structure, called an NROM, for flash memories. This latter work in Israel and Germany is based on employing charge trapping in a silicon nitride layer in a non-conventional flash memory device structure. (See generally, B. Eitan et al., “Characterization of Channel Hot Electron Injection by the Subthreshold Slope of NROM device,” IEEE Electron Device Lett., Vol. 22, No. 11, pp. 556-558, (November 2001); B. Etian et al., “NROM: A novel localized Trapping, 2-Bit Nonvolatile Memory Cell,” IEEE Electron Device Lett., Vol. 21, No. 11, pp. 543-545, (November 2000)). Charge trapping in silicon nitride gate insulators was the basic mechanism used in MNOS memory devices (see generally, S. Sze, Physics of Semiconductor Devices, Wiley, N.Y., 1981, pp. 504-506), charge trapping in aluminum oxide gates was the mechanism used in MIOS memory devices (see generally, S. Sze, Physics of Semiconductor Devices, Wiley, N.Y., 1981, pp. 504-506), and the present inventors have previously disclosed charge trapping at isolated point defects in gate insulators (see generally, L. Forbes and J. Geusic, “Memory using insulator traps,” U.S. Pat. No. 6,140,181, issued Oct. 31, 2000).

In contrast to the above work, the present invention disclosures programming a MOSFET in a reverse direction to trap one of a number of charge levels near the source region and reading the device in a forward direction to form a multistate memory cell based on a modification of DRAM technology.

Prior art DRAM technology generally employs silicon oxide as the gate insulator. Further the emphasis in conventional DRAM devices is placed on trying to minimize charge trapping in the silicon oxide gate insulator. According to the teachings of the present invention, a variety of insulators are used to trap electrons more efficiently than in silicon oxide. That is, in the present invention, the multistate memory cell employs charge trapping in gate insulators such as, wet silicon oxide, silicon nitride, silicon oxynitride SON, silicon rich oxide SRO, aluminum oxide Al₂O₃, composite layers of these insulators such as oxide and then silicon nitride, or oxide and then aluminum oxide, or multiple layers as oxide-nitride-oxide. While the charge trapping efficiency of silicon oxide may be low such is not the case for silicon nitride or composite layers of silicon oxide and nitride.

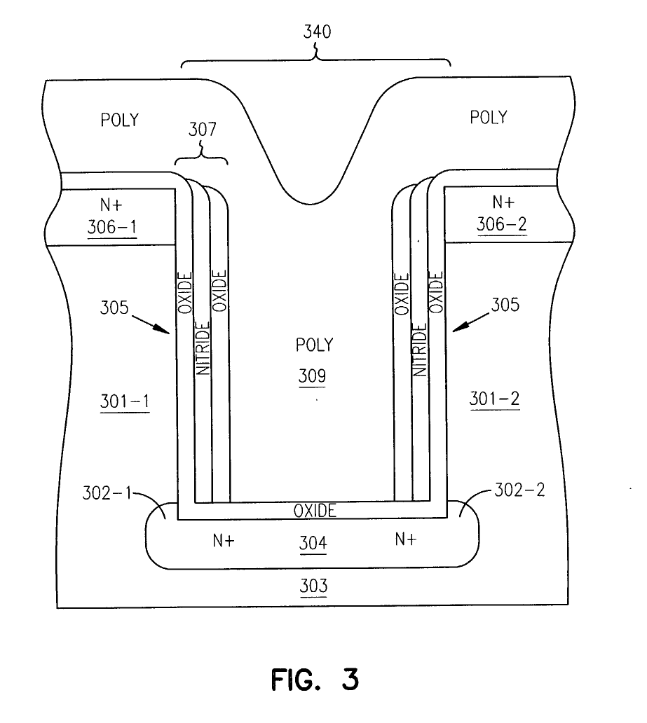

FIG. 3 illustrates a portion of a memory array 300 according to the teachings of the present invention. The memory in FIG. 3, is shown illustrating a number of vertical pillars, or multistate cells, 301-1 and 301-2 formed according to the teachings of the present invention. As one of ordinary skill in the art will appreciate upon reading this disclosure, the number of vertical pillar are formed in rows and columns extending outwardly from a substrate 303. As shown in FIG. 3, the number of vertical pillars, 301-1 and 301-2 are separated by a number of trenches 340. According to the teachings of the present invention, the number of vertical pillars, 301-1 and 301-2, serve as transistors including a first source/drain region, 302-1 and 302-2 respectively. The first source/drain region, 302-1 and 302-2, is coupled to a sourceline 304. As shown in FIG. 3, the sourceline 304 is formed in a bottom of the trenches 340 between rows of the vertical pillars, 301-1 and 301-2. In one embodiment, according to the teachings of the present invention, the sourceline 304 is formed from a doped region implanted in the bottom of the trench. A second source/drain region, 306-1 and 306-2 respectively, is coupled to a bitline (not shown). A channel region 305 is located between the first and the second source/drain regions.

As shown in FIG. 3, a gate 307 is separated from the channel region 305 by a gate insulator 307 in the trenches 340 along rows of the vertical pillars, 301-1 and 301-2. In one embodiment, according to the teachings of the present invention, the gate insulator 307 includes a gate insulator 307 selected from the group of silicon dioxide (SiO₂) formed by wet oxidation, silicon oxynitride (SON), silicon rich oxide (SRO), and aluminum oxide (Al₂O₃). In another embodiment, according to the teachings of the present invention, the gate insulator 307 includes a gate insulator 307 selected from the group of silicon rich aluminum oxide insulators, silicon rich oxides with inclusions of nanoparticles of silicon, silicon oxide insulators with inclusions of nanoparticles of silicon carbide, and silicon oxycarbide insulators. In another embodiment, according to the teachings of the present invention, the gate insulator 307 includes a composite layer 307. In this embodiment, the composite layer 307 includes a composite layer 307 selected from the group of an oxide-aluminum oxide (Al₂O₃)-oxide composite layer, and oxide-silicon oxycarbide-oxide composite layer. In another embodiment, the composite layer 307 includes a composite layer 307, or a non-stoichiometric single layer, of two or more materials selected from the group of silicon (Si), titanium (Ti), and tantalum (Ta). In another embodiment, according to the teachings of the present invention, the gate insulator 307 includes an oxide-nitride-oxide (ONO) gate insulator 307.

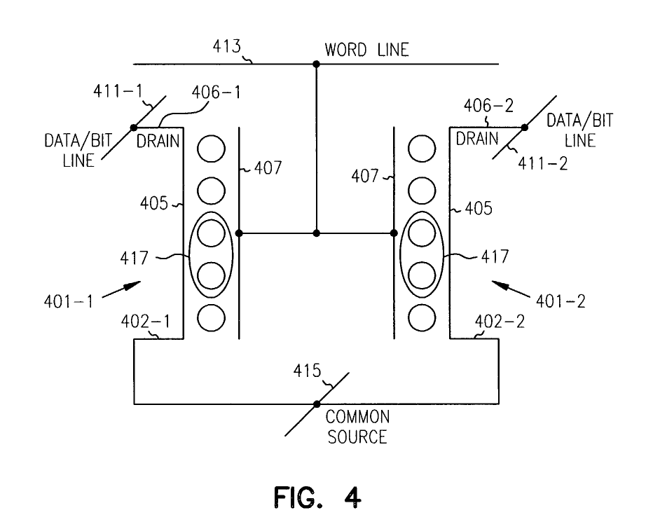

FIG. 4 illustrates an electrical equivalent circuit 400 for the portion of the memory array shown in FIG. 3. As shown in FIG. 4, a number of vertical multistate cells, 401-1 and 401-2, are provided. Each vertical multistate cell, 401-1 and 401-2, includes a first source/drain region, 402-1 and 402-2, a second source/drain region 406-1 and 406-2, a channel region 405 between the first and the second source/drain regions, and a gate 409 separated from the channel region by a gate insulator 407.

FIG. 4 further illustrates a number of bit lines, 411-1 and 411-2, coupled to the second source/drain region 406-1 and 406-2 of each multistate cell. In one embodiment, as shown in FIG. 4, the number of bit lines, 411-1 and 411-2, are coupled to the second source/drain region 406-1 and 406-2 along rows of the memory array. A number of word lines, such as wordline 413 in FIG. 4, are coupled to the gate 409 of each multistate cell along columns of the memory array. And, a number of sourcelines, such as common sourceline 415, are coupled to the first source/drain regions, e.g. 402-1 and 402-2, along columns of the vertical multistate cells, 401-1 and 401-2, such that adjacent pillars containing these transistors share the common sourceline 415. In one embodiment, column adjacent pillars include a transistor which operates as a vertical multistate cell, e.g. 401-1, on one side of a shared trench, the shared trench separating rows of the pillars as described in connection with FIG. 3, and a transistor which operates as a reference cell, e.g. 401-2, having a programmed conductivity state on the opposite side of the shared trench. In this manner, according to the teachings of the present invention and as described in more detail below, at least one of multistate cells can be programmed to have one of a number of charge levels trapped in the gate insulator, shown generally as 417, adjacent to the first source/drain region, e.g. 402-1, such that the channel region 405 will have a first voltage threshold region (Vt1) and a second voltage threshold region (Vt2) and such that the programmed multistate cell operates at reduced drain source current.

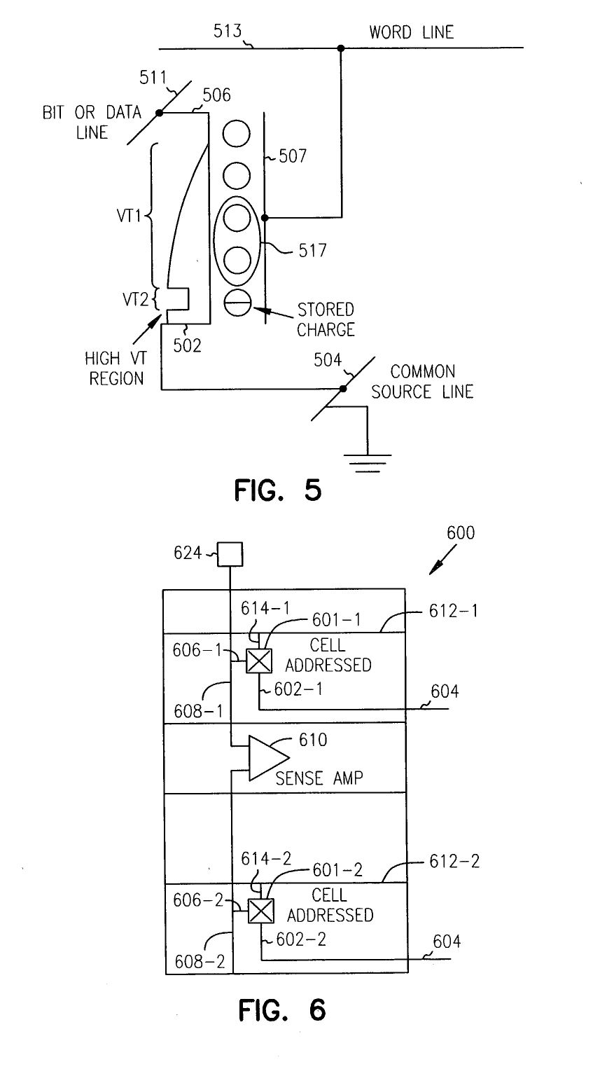

FIG. 5 is another electrical equivalent circuit useful in illustrating a read operation on the novel multistate cell 500 according to the teachings of the present invention. The electrical equivalent circuit in FIG. 5 represents a programmed vertical multistate cell. As explained in detail in connection with FIG. 3, the programmed vertical multistate cell 500 includes a vertical metal oxide semiconductor field effect transistor (MOSFET) 500 extending outwardly from a substrate. The MOSFET has a source region 502, a drain region 506, a channel region 505 between the source region 502 and the drain region 506, and a gate 507 separated from the channel region 505 by a gate insulator, shown generally as 517.

As shown in FIG. 5 a wordline 513 is coupled to the gate 507. A sourceline 504, formed in a trench adjacent to the vertical MOSFET as described in connection with FIG. 3, is coupled to the source region 502. A bit line, or data line 511 is coupled to the drain region 506. The multistate cell 500 shown in FIG. 5 is an example of a programmed multistate cell 500 having one of a number of charge levels trapped in the gate insulator, shown generally as 517, adjacent to the first source/drain region, 502, such that the channel region 505 will have a first voltage threshold region (Vt1) and a second voltage threshold region (Vt2) and such that the programmed multistate cell 500 operates at reduced drain source current. According to the teachings of the present invention, the second voltage threshold region (Vt2) is now a high voltage threshold region which is greater than the first voltage threshold region (Vt1).

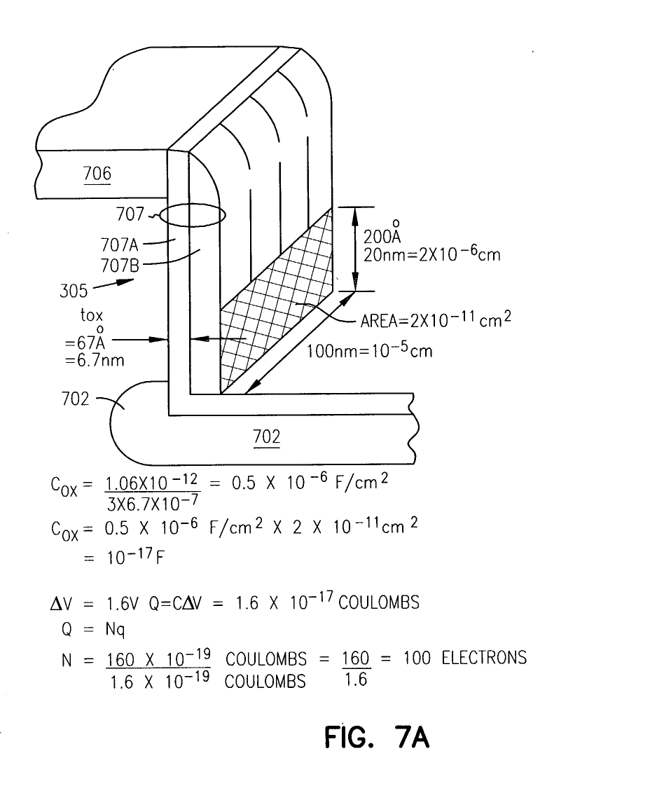

FIG. 6 illustrates a portion of a memory array 600 according to the teachings of the present invention. The memory in FIG. 6, is shown illustrating a pair of multistate cells 601-1 and 601-2 formed according to the teachings of the present invention. As one of ordinary skill in the art will understand upon reading this disclosure, any number of multistate cells can be organized in an array, but for ease of illustration only two are displayed in FIG. 6. As shown in FIG. 6, a first source/drain region, 602-1 and 602-2 respectively, is coupled to a sourceline 604. A second source/drain region, 606-1 and 606-2 respectively, is coupled to a bitline, 608-1 and 608-2 respectively. Each of the bitlines, 608-1 and 608-2, couple to a sense amplifier, shown generally at 610. A wordline, 612-1 and 612-2 respectively, is couple to a gate, 614-1 and 614-2 respectively, for each of the multistate cells, 601-1 and 601-2. According to the teachings of the present invention, the wordlines, 612-1 and 612-2, run across or are perpendicular to the rows of the memory array 600. Finally, a write data/precharge circuit is shown at 624 for coupling a first or a second potential to bitline 608-1. As one of ordinary skill in the art will understand upon reading this disclosure, the write data/precharge circuit 624 is adapted to couple either a ground to the bitline 608-1 during a write operation in the reverse direction, or alternatively to precharge the bitline 608-1 to fractional voltage of VDD during a read operation in the forward direction. As one of ordinary skill in the art will understand upon reading this disclosure, the sourceline 604 can be biased to a voltage higher than VDD during a write operation in the reverse direction, or alternatively grounded during a read operation in the forward direction.

As shown in FIG. 6, the array structure 600, including multistate cells 601-1 and 601-2, has no capacitors. Instead, according to the teachings of the present invention, the first source/drain region or source region, 602-1 and 602-2, are coupled directly to the sourceline 604. In order to write, the sourceline 604 is biased to voltage higher than VDD and the devices stressed in the reverse direction by grounding the data or bit line, 608-1 or 608-2. If the multistate cell, 601-1 or 601-2, is selected by a word line address, 612-1 or 612-2, then the multistate cell, 601-1 or 601-2, will conduct and be stressed with accompanying hot electron injection into the cells gate insulator adjacent to the source region, 602-1 or 602-2. As one of ordinary skill in the art will understand upon reading this disclosure, a number of different charge levels can be programmed into the gate insulator adjacent to source region such that the cells is used as a differential cell and/or the cell is compared to a reference or dummy cell, as shown in FIG. 6, and multiple bits can be stored on the multistate cell.

During read the multistate cell, 601-1 or 601-2, is operated in the forward direction with the sourceline 604 grounded and the bit line, 608-1 or 608-2, and respective second source/drain region or drain region, 606-1 and 606-2, of the cells precharged to some fractional voltage of Vdd. If the device is addressed by the word line, 612-1 or 612-2, then its conductivity will be determined by the presence or absence of the amount of stored charge trapped in the gate insulator as measured or compared to the reference or dummy cell and so detected using the sense amplifier 610. The operation of DRAM sense amplifiers is described, for example, in U.S. Pat. Nos. 5,627,785; 5,280,205; and 5,042,011, all assigned to Micron Technology Inc., and incorporated by reference herein. The array would thus be addressed and read in the conventional manner used in DRAM's, but programmed as multistate cells in a novel fashion.

In operation the devices would be subjected to hot electron stress in the reverse direction by biasing the sourceline 604, and read while grounding the sourceline 604 to compare a stressed multistate cell, e.g. cell 601-1, to an unstressed dummy device/cell, e.g. 601-2, as shown in FIG. 6. The write and possible erase feature could be used during manufacture and test to initially program all cells or devices to have similar or matching conductivity before use in the field. Likewise, the transistors in the reference or dummy cells, e.g. 601-2, can all initially be programmed to have the same conductivity states. According to the teachings of the present invention, the sense amplifier 610 can then detect small differences in cell or device characteristics due to stress induced changes in device characteristics during the write operation.

As one of ordinary skill in the art will understand upon reading this disclosure such arrays of multistate cells are conveniently realized by a modification of DRAM technology. According to the teachings of the present invention a gate insulator of the multistate cell includes gate insulators selected from the group of thicker layers of SiO₂ formed by wet oxidation, SON silicon oxynitride, SRO silicon rich oxide, Al₂O₃ aluminum oxide, composite layers and implanted oxides with traps (L. Forbes and J. Geusic, “Memory using insulator traps,” Micron disclosure 97-0049, U.S. Pat. No. 6,140,181 Oct. 31, 2000). Conventional transistors for address decode and sense amplifiers can be fabricated after this step with normal thin gate insulators of silicon oxide.

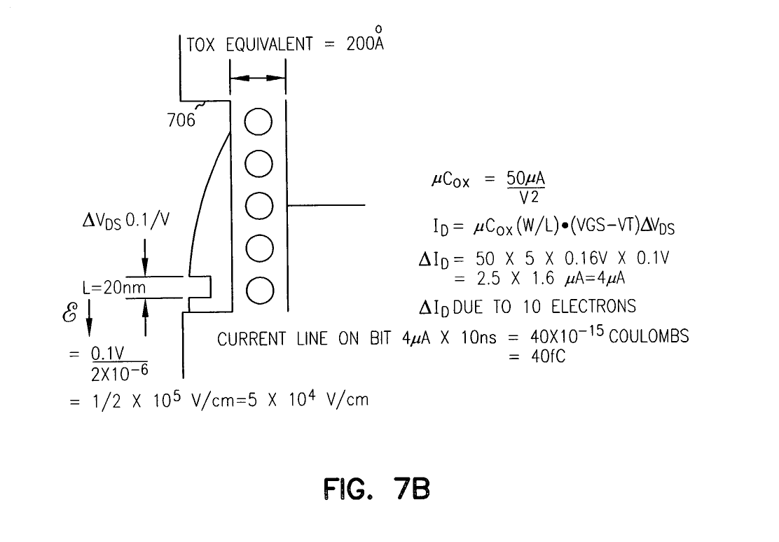

FIGS. 7A-7B and 8-9 are useful in illustrating the use of charge storage in the gate insulator to modulate the conductivity of the multistate cell according to the teachings of the present invention. That is, FIGS. 7A-9 illustrates the operation of the novel multistate cell 701 formed according to the teachings of the present invention. As shown in FIG. 7A, the gate insulator 707 has a number of layers, e.g. an ONO stack, where layer 707A is the oxide layer closest to the channel 705 and a nitride layer 707B is formed thereon. In the embodiment shown in FIG. 7A the oxide layer 707A is illustrated having a thickness of approximately 6.7 nm or 67 Å (roughly 10⁻⁶ cm). In the embodiment shown in FIG. 7A a multistate cell is illustrated having dimensions of 0.1 μm (10⁻⁵ cm) by 0.1 μm. For purposes of illustration, the charge storage region near the source can reasonably have dimensions of 0.1 micron (1000 Å) by 0.02 micron (200 Å) in a 0.1 micron technology. If the gate oxide 707A nearest the channel 705 is 67 Å then a charge of 100 electrons will cause a threshold voltage shift in this region of 1.6 Volts since the oxide capacitance is about 0.5 micro-Farad (μF) per square centimeter. If the transistor has a total effective oxide thickness of 200 Å then a change in the threshold voltage of only 0.16 Volts near the source, corresponding to 10 electrons, is estimated to change the transistor current by 4 micro Amperes (μA). The sense amplifier described in connection with FIG. 6, which is similar to a DRAM sense amplifier, can easily sense this charge difference on the data or bitlines. In this embodiment, the sensed charge difference on the data or bitlines will be 40 femto Coulombs (fC) over a sense period of 10 nano seconds (nS).

To illustrate these numbers, the capacitance, Ci, of the structure depends on the dielectric constant, ε₁ (which for silicon dioxide SiO₂ equates to 1.06/3×10⁻¹² F/cm), and the thickness of the insulating layers, t, (given here as 6.7×10⁻⁷ cm), such that Ci=εi/t=((1.06×10⁻¹²F/cm/(3×6.7×10⁻⁷ cm))=0.5×10⁻⁶ Farads/cm² (F/cm²). This value taken over the charge storage region near the source, e.g. 20 nm×100 nm or 2×10⁻¹¹ cm², results in a capacitance value of Ci=10⁻¹⁷ Farads. Thus, for a change in the threshold voltage of ΔV=1.6 Volts the stored charge must be Q=C×ΔV=(10⁻¹⁷ Farads×1.6 Volts)=1.6×10⁻¹⁷ Coulombs. Since Q=Nq, the number of electrons stored is approximately Q/q=(1.6×10⁻¹⁷ Coulombs/1.6×10⁻¹⁹ Coulombs) or 100 electrons. In effect, the programmed multistate cell, or modified MOSFET is a programmed MOSFET having a charge trapped in the gate insulator adjacent to a first source/drain region, or source region, such that the channel region has a first voltage threshold region (Vt1) and a second voltage threshold region (Vt2), where Vt2 is greater than Vt1, and Vt2 is adjacent the source region such that the programmed MOSFET operates at reduced drain source current. For ΔQ=100 electrons in the dimensions given above, if the transistor has a total effective oxide thickness of 200 Å then a change in the threshold voltage of only 0.16 Volts near the source, corresponding to 10 electrons, is estimated to change the transistor current by 4 micro Amperes (μA). As stated above, the sense amplifier described in connection with FIG. 6, which is similar to a DRAM sense amplifier, can easily sense this charge difference on the data or bitlines. And, the sensed charge difference on the data or bitlines will be 40 femto Columbs (fC) over a sense period of 10 nano seconds (nS) for this representative one of a number of stored charge levels according to the teachings of the present invention. Again, a number of different charge levels can be programmed into the gate insulator adjacent to source region such that the cell is used as a differential cell and/or the cell is compared to a reference or dummy cell, as shown in FIG. 6, and multiple bits can be stored on the multistate cell of the present invention.

FIG. 7B aids to further illustrate the conduction behavior of the novel multistate cell of the present invention. The electrical equivalent circuit shown in FIG. 7B illustrates a multistate cell 701 having an equivalent oxide thickness of 200 Å. The charge storage region near the source 702 can reasonably have a length dimension of 0.02 micron (20 nm) in a 0.1 micron technology with a width dimension of 0.1 micron (100 nm). Therefore, for a change in the drain source voltage (ΔV_{DS}) in this region an electric field of E=(0.1V/2×10⁻⁶ cm)=0.5×10⁵ V/cm or 5×10⁴ V/cm is provided. The drain current is calculated using the formula I_{D}=μC_{OX}×(W/L)×(Vgs−Vt)×ΔV_{DS}. In this example, μC_{OX}=μC₁ is taken as 50 μA/V² and W/L=5. Appropriate substitution into the drain current provides I_{D}=(50 μA/V²×5×0.16 Volts×0.1 Volts)=2.5×1.6 μA=4 μA. As noted above this drain current I_{D} corresponds to 10 electrons trapped in the gate insulator, or charge storage region 707 near the source 702. Sensed over a period of 10 nanoSeconds (nS) produces a current on the bitline of 40 fC (e.g. 4 μA×10 nS=40×10⁻¹⁵ Columbs).

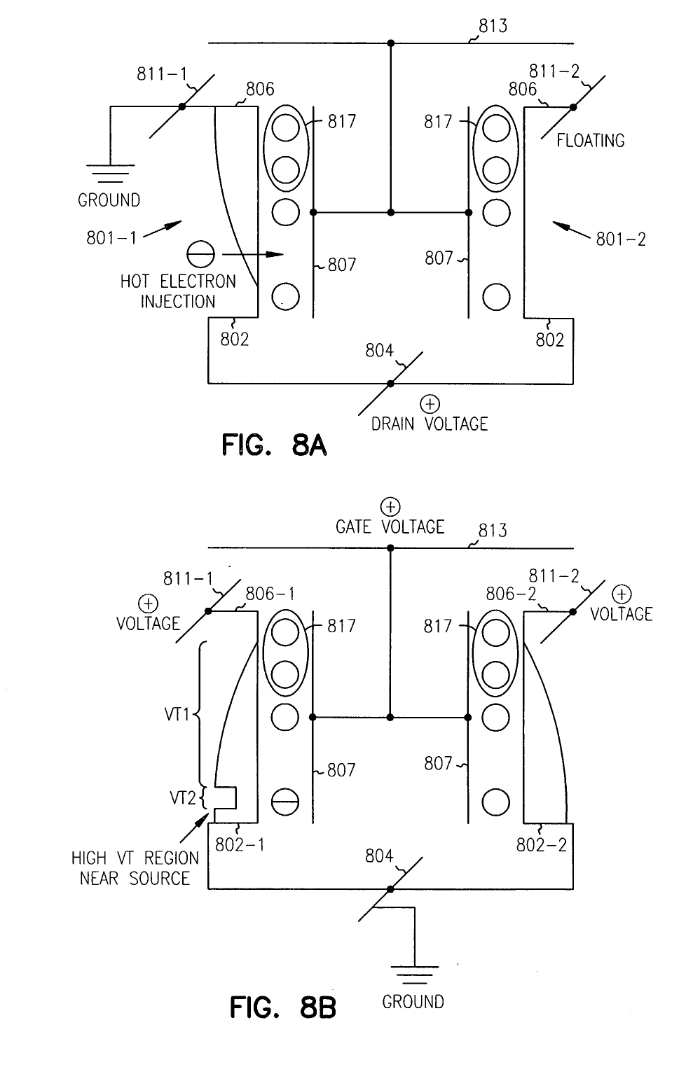

FIGS. 8A and 8B, illustrate the operation and programming the novel multistate cell as described above. However, FIGS. 8A and 8B also help illustrate an alternative array configuration where adjacent devices are compared and one of the devices on the opposite side of a shared trench is used as a dummy cell transistor or reference device. Again, the reference devices can all be programmed to have the same initial conductivity state. FIG. 8A illustrates the operation and programming the novel multistate cell in the reverse direction. As shown in FIG. 8A, a transistor 801-1 on one side of the trench (as described in connection with FIG. 3) is stressed by grounding its respective drain line, e.g. 811-1. As shown in FIG. 8A, the drain line 811-2 for the transistor 801-2 on the opposite side of the trench is left floating. A voltage is applied to the shared sourceline 804 located at the bottom of the trench (as described in connection with FIG. 3) which now acts as a drain. As shown in this electrical equivalent circuit, the neighboring (shared trench)/column adjacent transistors, 801-1 and 801-2, share a gate 807 and the wordline 813, e.g. polysilicon gate lines, coupling thereto run across or are perpendicular to the rows containing the bit and source lines, e.g. 811-1, 811-2, and 804. A gate voltage is applied to the gates 807. Here the multistate cell 801-1 will conduct and be stressed with accompanying hot electron injection into the cells gate insulator 817 adjacent to the source region 802-1.

FIG. 8B illustrates the now programmed multistate cell's operation in the forward direction and differential read occurring in a this differential cell embodiment, e.g. 2 transistors in each cell. To read this state the drain and source (or ground) have the normal connections and the conductivity of the multistate cell is determined. That is, the drain line, 811-1 and 811-2, have the normal forward direction potential applied thereto. The shared sourceline 804 located at the bottom of the trench (as described in connection with FIG. 3) is grounded and once again acts as a source. And, a gate voltage is applied to the gates 807. As one of ordinary skill in the art will understand upon reading this disclosure, a number of different charge levels can be programmed into the gate insulator 817 adjacent to source region 802-1 and compared to the reference or dummy cell, 802-2. Thus, according to the teachings of present invention multiple bits can be stored on the multistate cell.

As stated above, these novel multistate cells can be used in a DRAM like array. Two transistors occupy an area of 4F squared (F=the minimum lithographic feature size) when viewed from above, or each memory cell consisting of one transistor has an area of 2F squared. Each transistor can now, however, store many bits so the data storage density is much higher than one bit for each 1F squared unit area. Using a reference or dummy cell for each memory transistor where the reference transistor is in close proximity, e.g. the embodiment shown in FIGS. 8A and 8B vs. that shown in FIG. 4, results in better matching characteristics of transistors, but a lower memory density.

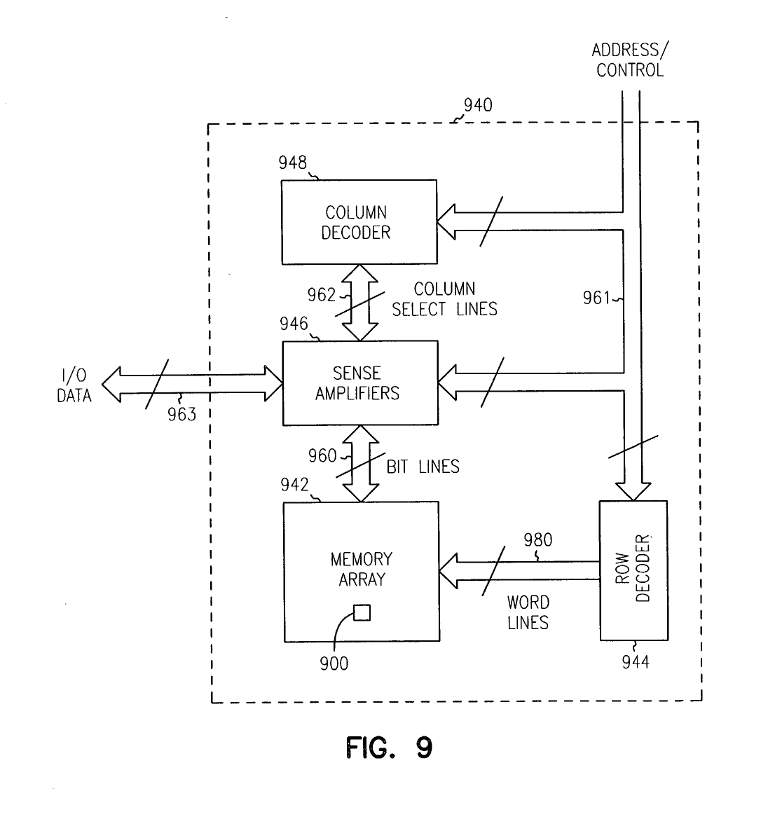

In FIG. 9 a memory device is illustrated according to the teachings of the present invention. The memory device 940 contains a memory array 942, row and column decoders 944, 948 and a sense amplifier circuit 946. The memory array 942 consists of a plurality of multistate cells 900, formed according to the teachings of the present invention whose word lines 980 and bit lines 960 are commonly arranged into rows and columns, respectively. The bit lines 960 of the memory array 942 are connected to the sense amplifier circuit 946, while its word lines 980 are connected to the row decoder 944. Address and control signals are input on address/control lines 961 into the memory device 940 and connected to the column decoder 948, sense amplifier circuit 946 and row decoder 944 and are used to gain read and write access, among other things, to the memory array 942.

The column decoder 948 is connected to the sense amplifier circuit 946 via control and column select signals on column select lines 962. The sense amplifier circuit 946 receives input data destined for the memory array 942 and outputs data read from the memory array 942 over input/output (I/O) data lines 963. Data is read from the cells of the memory array 942 by activating a word line 980 (via the row decoder 944), which couples all of the memory cells corresponding to that word line to respective bit lines 960, which define the columns of the array. One or more bit lines 960 are also activated. When a particular word line 980 and bit lines 960 are activated, the sense amplifier circuit 946 connected to a bit line column detects and amplifies the conduction sensed through a given multistate cell, where in the read operation the source region of a given cell is couple to a grounded array plate (not shown), and transferred its bit line 960 by measuring the potential difference between the activated bit line 960 and a reference line which may be an inactive bit line. The operation of Memory device sense amplifiers is described, for example, in U.S. Pat. Nos. 5,627,785; 5,280,205; and 5,042,011, all assigned to Micron Technology Inc., and incorporated by reference herein.

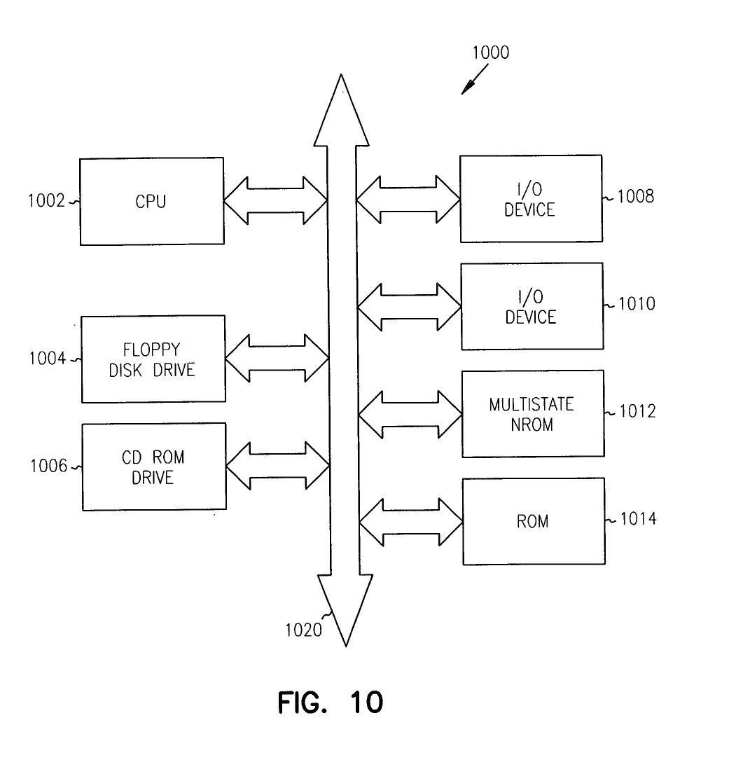

FIG. 10 is a block diagram of an electrical system, or processor-based system, 1000 utilizing multistate memory cells 1012 constructed in accordance with the present invention. That is, the multistate memory cells 1012 utilizes the modified DRAM cell as explained and described in detail in connection with FIGS. 2-4. The processor-based system 1000 may be a computer system, a process control system or any other system employing a processor and associated memory. The system 1000 includes a central processing unit (CPU) 1002, e.g., a microprocessor, that communicates with the multistate memory 1012 and an I/O device 1008 over a bus 1020. It must be noted that the bus 1020 may be a series of buses and bridges commonly used in a processor-based system, but for convenience purposes only, the bus 1020 has been illustrated as a single bus. A second I/O device 1010 is illustrated, but is not necessary to practice the invention. The processor-based system 1000 can also includes read-only memory (ROM) 1014 and may include peripheral devices such as a floppy disk drive 1004 and a compact disk (CD) ROM drive 1006 that also communicates with the CPU 1002 over the bus 1020 as is well known in the art.

It will be appreciated by those skilled in the art that additional circuitry and control signals can be provided, and that the memory device 1000 has been simplified to help focus on the invention. At least one of the multistate cell in NROM 1012 includes a programmed MOSFET having a charge trapped in the gate insulator adjacent to a first source/drain region, or source region, such that the channel region has a first voltage threshold region (Vt1) and a second voltage threshold region (Vt2), where Vt2 is greater than Vt1, and Vt2 is adjacent the source region such that the programmed MOSFET operates at reduced drain source current.

It will be understood that the embodiment shown in FIG. 10 illustrates an embodiment for electronic system circuitry in which the novel memory cells of the present invention are used. The illustration of system 1000, as shown in FIG. 10, is intended to provide a general understanding of one application for the structure and circuitry of the present invention, and is not intended to serve as a complete description of all the elements and features of an electronic system using the novel memory cell structures. Further, the invention is equally applicable to any size and type of memory device 1000 using the novel memory cells of the present invention and is not intended to be limited to that described above. As one of ordinary skill in the art will understand, such an electronic system can be fabricated in single-package processing units, or even on a single semiconductor chip, in order to reduce the communication time between the processor and the memory device.

Applications containing the novel memory cell of the present invention as described in this disclosure include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

Conclusion

Utilization of a modification of well established DRAM technology and arrays will serve to afford an inexpensive memory device which can be regarded as disposable if the information is later transferred to another medium, for instance CDROM's. The high density of DRAM array structures will afford the storage of a large volume of digital data or images at a very low cost per bit. There are many applications where the data need only be written a limited number of times, the low cost of these memories will make it more efficient to just utilize a new memory array, and dispose of the old memory array, rather than trying to erase and reuse these arrays as is done with current flash memories. The novel multistate cells can be used in a DRAM like array. Two transistors occupy an area of 4F squared (F=the minimum lithographic feature size) when viewed from above, or each memory cell consisting of one transistor has an area of 2F squared. Each transistor can now, however, store many bits so the data storage density is much higher than one bit for each 1F squared unit area. Using a reference or dummy cell for each memory transistor where the reference transistor is in close proximity, e.g. the embodiment shown in FIGS. 8A and 8B vs. that shown in FIG. 4, results in better matching characteristics of transistors, but a lower memory density.

It is to be understood that the above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. A vertical multistate cell, comprising:
a vertical metal oxide semiconductor field effect transistor (MOSFET) extending outwardly from a substrate, the MOSFET having a first source/drain region, a second source/drain region, a channel region between the first and the second source/drain regions, and a gate separated from the channel region by a gate insulator;
a sourceline formed in a trench adjacent to the vertical MOSFET, wherein the first source/drain region is coupled to the sourceline;
a transmission line coupled to the second source/drain region; and
wherein the MOSFET is a programmed MOSFET having one of a number of charge levels trapped in the gate insulator adjacent to the first source/drain region such that the channel region has a first voltage threshold region (Vt1) and a second voltage threshold region (Vt2) and such that the programmed MOSFET operates at reduced drain source current.

2. The multistate cell of claim 1, wherein the first source/drain region of the MOSFET includes a source region and the second source/drain region of the MOSFET includes a drain region.

3. The multistate cell of claim 1, wherein the transmission line includes a bit line.

4. The multistate cell of claim 1, wherein the number of charge levels trapped in the gate insulator adjacent the first source/drain region includes a trapped electron charge.

5. The multistate cell of claim 1, wherein the second voltage threshold region (Vt2) in the channel is adjacent the first source/drain region, and wherein the first voltage threshold region (Vt1) in the channel is adjacent the second source/drain region.

6. The multistate cell of claim 5, wherein the Vt2 has a higher voltage threshold than the Vt1.

7. The multistate cell of claim 1, wherein the gate insulator has a thickness of approximately 10 nanometers (nm).

8. The multistate cell of claim 7, wherein the gate insulator includes a gate insulator selected from the group of silicon dioxide (SiO₂) formed by wet oxidation, silicon oxynitride (SON), silicon rich oxide (SRO), and aluminum oxide (Al₂O₃).

9. A vertical multistate cell, comprising:
a vertical metal oxide semiconductor field effect transistor (MOSFET) extending outwardly from a substrate, the MOSFET having a source region, a drain region, a channel region between the source region and the drain region, and a gate separated from the channel region by a gate insulator;
a wordline coupled to the gate;
a sourceline formed in a trench adjacent to the vertical MOSFET, wherein the source region is coupled to the sourceline;
a bit line coupled to the drain region; and
wherein the MOSFET is a programmed MOSFET having a number of charge levels trapped in the gate insulator adjacent to the source region such that the channel region has a first voltage threshold region (Vt1) adjacent to the drain region and a second voltage threshold region (Vt2) adjacent to the source region, the Vt2 having a greater voltage threshold than Vt1.

10. The multistate cell of claim 9, wherein the gate insulator has a thickness of approximately 10 nanometers (nm).

11. The multistate cell of claim 10, wherein the gate insulator includes a gate insulator selected from the group of silicon rich aluminum oxide insulators, silicon rich oxides with inclusions of nanoparticles of silicon, silicon oxide insulators with inclusions of nanoparticles of silicon carbide, and silicon oxycarbide insulators.

12. The multistate cell of claim 9, wherein the gate insulator includes a composite layer.

13. The multistate cell of claim 12, wherein the composite layer includes a composite layer selected from the group of an oxide-aluminum oxide (Al₂O₃)-oxide composite layer, and oxide-silicon oxycarbide-oxide composite layer.

14. The multistate cell of claim 12, wherein the composite layer includes a composite layer, or a non-stoichiometric single layer of two or more materials selected from the group of silicon (Si), titanium (Ti), and tantalum (Ta).

15. The multistate cell of claim 9, wherein the gate insulator includes a multiple layer of oxide-nitride-oxide (ONO).

16. A memory array, comprising:
a number of vertical multistate cells extending from a substrate and separated by trenches, wherein each vertical multistate cell includes a first source/drain region, a second source/drain region, a channel region between the first and the second source/drain regions, and a gate separated from the channel region by a gate insulator;
a number of bit lines coupled to the second source/drain region of each multistate cell along rows of the memory array;
a number of word lines coupled to the gate of each multistate cell along columns of the memory array;
a number of sourcelines, wherein the first source/drain region of each vertical multistate cell is coupled to the number of sourcelines along rows in trenches between the number of vertical multistate cells extending from a substrate; and
wherein at least one of multistate cells is a programmed MOSFET having one of a number of charge levels trapped in the gate insulator adjacent to the first source/drain region such that the channel region has a first voltage threshold region (Vt1) and a second voltage threshold region (Vt2) and such that the programmed MOSFET operates at reduced drain source current.

17. The memory array of claim 16, wherein the one of a number of charge levels trapped in the gate insulator includes a charge adjacent to the source of approximately 10 electrons.

18. The memory array of claim 16, wherein the first source/drain region of the MOSFET includes a source region and the second source/drain region of the MOSFET includes a drain region.

19. The memory array of claim 16, wherein the second voltage threshold region (Vt2) in the channel is adjacent the first source/drain region, and wherein the first voltage threshold region (Vt1) in the channel is adjacent the second source/drain region, and wherein Vt2 has a higher voltage threshold than the Vt1.

20. The memory array of claim 16, wherein the gate insulator of each multistate cell has a thickness of approximately 10 nanometers (nm).

21. The memory array of claim 20, wherein the gate insulator includes a gate insulator selected from the group of silicon dioxide (SiO₂) formed by wet oxidation, silicon oxynitride (SON), and silicon rich aluminum oxide.

22. The memory array of claim 20, wherein the number of vertical multistate cells extending from a substrate operate as equivalent to a transistor having a size of much less than 1.0 lithographic feature squared (1F²).

23. A memory array, comprising:
a number of vertical pillars formed in rows and columns extending outwardly from a substrate and separated by a number of trenches, wherein the number of vertical pillars serve as transistors including a first source/drain region, a second source/drain region, a channel region between the first and the second source/drain regions, and a gate separated from the channel region by a gate insulator in the trenches along rows of pillars, wherein along columns of the pillars adjacent pillars include a transistor which operates as a multistate cell on one side of a trench and a transistor which operates as a reference cell having a programmed conductivity state on the opposite side of the trench;
a number of bit lines coupled to the second source/drain region of each transistor along rows of the memory array;
a number of word lines coupled to the gate of each transistor along columns of the memory array;
a number of sourcelines formed in a bottom of the trenches between rows of the pillars and coupled to the first source/drain regions of each transistor along rows of pillars, wherein along columns of the pillars the first source/drain region of each transistor in column adjacent pillars couple to the sourceline in a shared trench such that a multistate cell transistor and a reference cell transistor share a common sourceline; and
wherein at least one of multistate cell transistors is a programmed MOSFET having one of a number of charge levels trapped in the gate insulator adjacent to the first source/drain region such that the channel region of that transistor has a first voltage threshold region (Vt1) and a second voltage threshold region (Vt2) and such that the programmed MOSFET operates at reduced drain source current.

24. The memory array of claim 23, wherein the number of sourcelines formed in a bottom of the trenches between rows of the pillars include a doped region implanted in the bottom of the trench.

25. The memory array of claim 23, wherein the one of a number of charge levels trapped in the gate insulator includes a charge adjacent to the source of approximately 10 electrons.

26. The memory array of claim 23, wherein the second voltage threshold region (Vt2) in the channel is adjacent the first source/drain region, and wherein the first voltage threshold region (Vt1) in the channel is adjacent the second source/drain region, and wherein Vt2 has a higher voltage threshold than the Vt1.

27. The memory array of claim 23, wherein the gate insulator of each multistate cell transistor has a thickness of approximately 10 nanometers (nm).

28. The memory array of claim 27, wherein the gate insulator of each multistate cell transistor includes a gate insulator selected from the group of silicon dioxide (SiO₂) formed by wet oxidation, silicon oxynitride (SON), and silicon rich aluminum oxide.

29. The memory array of claim 23, wherein each multistate cell transistors operate as equivalent to a transistor having a size of much less than 1.0 lithographic feature squared (1F²).

30. A memory device, comprising:
a memory array, wherein the memory array includes a number of vertical multistate cells extending outwardly from a substrate and separated by trenches, wherein each multistate cell includes a source region, a drain region, a channel region between the source and the drain regions, and a gate separated from the channel region by a gate insulator;
a number of bitlines coupled to the drain region of each vertical multistate cell along rows of the memory array;
a number of wordlines coupled to the gate of each vertical multistate cell along columns of the memory array;
a number of sourcelines, wherein the first source/drain region of each vertical multistate cell is coupled to the number of sourcelines along rows in trenches between the number of vertical multistate cells extending from a substrate;
a wordline address decoder coupled to the number of wordlines;
a bitline address decoder coupled to the number of bitlines;
a sense amplifier coupled to the number of bitlines, wherein each sense amplifier is further coupled to a number of reference cells having a programmed conductivity state; and
wherein at least one of multistate cells is a programmed MOSFET having a one or more charge levels trapped in the gate insulator adjacent to the source region such that the channel region has a first voltage threshold region (Vt1) and a second voltage threshold region (Vt2) and such that the programmed MOSFET operates at reduced drain/source current.

31. The memory device of claim 30, wherein the one or more charge levels trapped in the gate insulator includes a charge adjacent to the source of approximately 10 electrons.

32. The memory device of claim 30, wherein the second voltage threshold region (Vt2) in the channel is adjacent the source region, and wherein the first voltage threshold region (Vt1) in the channel is adjacent the drain region, and wherein Vt2 has a higher voltage threshold than the Vt1.

33. The memory device of claim 32, wherein the gate insulator of each multistate cell transistor includes an oxide-nitride-oxide (ONO) insulator.

34. The memory device of claim 33, wherein the gate insulator of each multistate cell has a thickness of approximately 10 nanometers (nm).

35. The memory device of claim 30, wherein the wordline address decoder and the bitline address decoder each include conventionally fabricated MOSFET transistors having thin gate insulators formed of silicon dioxide (SiO₂).

36. The memory device of claim 30, wherein the sense amplifier includes conventionally fabricated MOSFET transistors having thin gate insulators formed of silicon dioxide (SiO₂).

37. An electronic system, comprising:
a processor; and
a memory device coupled to the processor, wherein the memory device includes a memory array, the memory array including;
a number of vertical pillars formed in rows and columns extending outwardly from a substrate and separated by a number of trenches, wherein the number of vertical pillars serve as transistors including a first source/drain region, a second source/drain region, a channel region between the first and the second source/drain regions, and a gate separated from the channel region by a gate insulator in the trenches along rows of pillars, wherein along columns of the pillars adjacent pillars include a transistor which operates as a multistate cell on one side of a trench and a transistor which operates as a reference cell having a programmed conductivity state on the opposite side of the trench;
a number of bit lines coupled to the second source/drain region of each transistor along rows of the memory array;
a number of word lines coupled to the gate of each transistor along columns of the memory array;
a number of sourcelines formed in a bottom of the trenches between rows of the pillars and coupled to the first source/drain regions of each transistor along rows of pillars, wherein along columns of the pillars the first source/drain region of each transistor in column adjacent pillars couple to the sourceline in a shared trench such that a multistate cell transistor and a reference cell transistor share a common sourceline; and
wherein at least one of multistate cell transistors is a programmed MOSFET having one of a number of charge levels trapped in the gate insulator adjacent to the first source/drain region such that the channel region of that transistor has a first voltage threshold region (Vt1) and a second voltage threshold region (Vt2) and such that the programmed MOSFET operates at reduced drain source current.

38. The electronic system of claim 37, wherein the one of the number of charge levels trapped in the gate insulator includes a charge of approximately 10 electrons.

39. The electronic system of claim 37, wherein the gate insulator of each multistate cell transistor includes a gate insulator selected from the group of silicon dioxide (SiO₂) formed by wet oxidation, silicon oxynitride (SON), and silicon rich aluminum oxide.

40. The electronic system of claim 37, wherein the gate insulator of each multistate cell transistor includes an oxide-nitride-oxide (ONO) insulator.

41. The electronic system of claim 37, wherein each multistate cell transistors operate as equivalent to a transistor having a size of much less than 1.0 lithographic feature squared (1F²).

42. The electronic system of claim 37, wherein, in a read operation, a sourceline for two column adjacent pillars sharing a trench is coupled to a ground potential, the drain regions of the column adjacent pillars sharing a trench are precharged to a fractional voltage of VDD, and the gate for each of the column adjacent pillars sharing a trench is addressed such that a conductivity state of a multistate cell memory cell transistor can be compared to a conductivity state of a reference cell.

43. The electronic system of claim 37, wherein, in a write operation, a sourceline for two column adjacent pillars sharing a trench is biased to a voltage higher than VDD, one of the drain regions of the column adjacent pillars sharing a trench is coupled to a ground potential, and the gate for each of the column adjacent pillars sharing a trench is addressed with a wordline potential.

44. A method for operating a memory, comprising:
programming one or more vertical MOSFETs extending outwardly from a substrate and separated by trenches in a DRAM array in a reverse direction, wherein each MOSFET in the DRAM array includes a source region, a drain region, a channel region between the source and the drain regions, and a gate separated from the channel region by a gate insulator in the trenches, wherein the DRAM array includes a number of sourcelines formed in a bottom of the trenches between rows of the vertical MOSFETs and coupled to the source regions of each transistor along rows the vertical MOSFETs, wherein along columns of the vertical MOSFETs the source region of each column adjacent vertical MOSFET couple to the sourceline in a shared trench, and wherein the DRAM array includes a number of bitlines coupled to the drain region along rows in the DRAM array, and wherein programming the one or more vertical MOSFETs in the reverse direction includes:
applying a first voltage potential to a drain region of the vertical MOSFET;
applying a second voltage potential to a source region of the vertical MOSFET;
applying a gate potential to a gate of the vertical MOSFET; and
wherein applying the first, second and gate potentials to the one or more vertical MOSFETs includes creating a hot electron injection into the gate insulator of the one or more MOSFETs adjacent to the source region such that the one or more vertical MOSFETs become programmed MOSFETs having one of a number of charge levels trapped in the gate insulator such that the programmed MOSFET operates at reduced drain source current in a forward direction.

45. The method of claim 44, wherein applying a first voltage potential to the drain region of the vertical MOSFET includes grounding the drain region of the vertical MOSFET.

46. The method of claim 44, wherein applying a second voltage potential to the source region includes applying a high voltage potential (VDD) to a sourceline coupled thereto.

47. The method of claim 44, wherein applying a gate potential to the gate of the vertical MOSFET includes applying a gate potential to the gate in order to create a conduction channel between the source and drain regions of the vertical MOSFET.

48. The method of claim 44, wherein the method further includes reading one or more vertical MOSFETs in the DRAM array by operating an addressed vertical MOSFET in a forward direction, wherein operating the vertical MOSFET in the forward direction includes:
grounding a sourceline for two column adjacent pillars sharing a trench;
precharging the drain regions of the column adjacent pillars sharing a trench to a fractional voltage of VDD; and
applying a gate potential of approximately 1.0 Volt to the gate for each of the column adjacent pillars sharing a trench such that a conductivity state of the addressed vertical MOSFET can be compared to a conductivity state of a reference cell.

49. The method of claim 44, wherein in creating a hot electron injection into the gate insulator of the one or more vertical MOSFETs adjacent to the source region includes creating a first threshold voltage region (Vt1) adjacent to the drain region and creating a second threshold voltage region (Vt2) adjacent to the source region.

50. The method of claim 44, wherein in creating a hot electron injection into the gate insulator of the one or more vertical MOSFETs adjacent to the source region includes changing a threshold voltage for the vertical MOSFET adjacent to the source by approximately 0.16 Volts.

51. A method for multistate memory, comprising:
writing to one or more vertical MOSFETs arranged in rows and columns extending outwardly from a substrate and separated by trenches in a DRAM array in a reverse direction, wherein each MOSFET in the DRAM array includes a source region, a drain region, a channel region between the source and the drain regions, and a gate separated from the channel region by a gate insulator in the trenches, wherein the DRAM array includes a number of sourcelines formed in a bottom of the trenches between rows of the vertical MOSFETs and coupled to the source regions of each transistor along rows the vertical MOSFETs, wherein along columns of the vertical MOSFETs the source region of each column adjacent vertical MOSFET couple to the sourceline in a shared trench, and wherein the DRAM array includes a number of bitlines coupled to the drain region along rows in the DRAM array, and wherein programming the one or more vertical MOSFETs in the reverse direction includes;
biasing a sourceline for two column adjacent vertical MOSFETs sharing a trench to a voltage higher than VDD;
grounding a bitline coupled to one of the drain regions of the two column adjacent vertical MOSFETs in the vertical MOSFET to be programmed applying a gate potential to the gate for each of the two column adjacent vertical MOSFETs to create a hot electron injection into the gate insulator of the vertical MOSFET to be programmed adjacent to the source region such that the addressed MOSFETs becomes a programmed MOSFET and will operate at reduced drain source current in a forward direction;
reading one or more vertical MOSFETs in the DRAM array in a forward direction, wherein reading the one or more MOSFETs in the forward direction includes;
grounding a sourceline for two column vertical MOSFETs sharing a trench;
precharging the drain regions of the two column adjacent vertical MOSFETs sharing a trench to a fractional voltage of VDD; and
applying a gate potential of approximately 1.0 Volt to the gate for each of the two column adjacent vertical MOSFETs sharing a trench such that a conductivity state of an addressed vertical MOSFET can be compared to a conductivity state of a reference cell.

52. The method of claim 51, wherein in creating a hot electron injection into the gate insulator of the addressed MOSFET adjacent to the source region includes creating a first threshold voltage region (Vt1) adjacent to the drain region and creating a second threshold voltage region (Vt2) adjacent to the source region, wherein Vt2 is greater that Vt1.

53. The method of claim 51, wherein in creating a hot electron injection into the gate insulator of the addressed MOSFET adjacent to the source region includes changing a threshold voltage for the MOSFET adjacent to the source by approximately 0.16 Volts.

54. The method of claim 51, wherein in creating a hot electron injection into the gate insulator of the addressed MOSFET adjacent to the source region includes trapping a stored charge in the gate insulator of the addressed MOSFET adjacent to the source of approximately 10 electrons.

55. The method of claim 51, wherein reading the one or more MOSFETs in the forward direction includes using a sense amplifier to detect whether an addressed MOSFET is a programmed MOSFET, wherein a programmed MOSFET will exhibit a change in an integrated drain current of approximately 4.0 μA when addressed over approximately 10 ns.

56. A method for forming a multistate memory array, comprising:
forming a number of vertical pillars in rows and columns extending outwardly from a substrate and separated by a number of trenches, wherein the number of vertical pillars serve as transistors including a first source/drain region, a second source/drain region, a channel region between the first and the second source/drain regions, and a gate separated from the channel region by a gate insulator in the trenches along rows of pillars, wherein along columns of the pillars adjacent pillars include a transistor which operates as a multistate cell on one side of a trench and a transistor which operates as a reference cell having a programmed conductivity state on the opposite side of the trench;
forming a number of bit lines coupled to the second source/drain region of each transistor along rows of the memory array;
forming a number of word lines coupled to the gate of each transistor along columns of the memory array;
forming a number of sourcelines formed in a bottom of the trenches between rows of the pillars and coupled to the first source/drain regions of each transistor along rows of pillars, wherein along columns of the pillars the first source/drain region of each transistor in column adjacent pillars couple to the sourceline in a shared trench such that a multistate cell transistor and a reference cell transistor share a common sourceline; and
wherein the number of vertical pillars can be programmed in a reverse direction to have a one of a number of charge levels trapped in the gate insulator adjacent to the first source/drain region by biasing a sourceline to a voltage higher than VDD, grounding a bitline, and selecting a gate by a wordline address.

57. The method of claim 56, wherein forming a number of sourcelines formed in a bottom of the trenches between rows of the pillars includes implanting a doped region in the bottom of the trench.

58. The method of claim 56, wherein, in forming a gate insulator above the channel region in the trenches along rows of pillars, the method includes forming a gate insulator having a thickness of at least 10 nanometers (nm).

59. The method of claim 56, wherein, in forming a gate insulator above the channel region in the trenches along rows of pillars, the method includes forming a gate insulator selected from the group of silicon dioxide (SiO₂) formed by wet oxidation, silicon oxynitride (SON), and silicon rich aluminum oxide.

60. The method of claim 56, wherein, in forming a gate insulator above the channel region in the trenches along rows of pillars, the method includes forming an oxide-nitride-oxide (ONO) insulator.

61. The method of claim 56, wherein forming a number of vertical pillars in rows and columns extending outwardly from a substrate and separated by a number of trenches, wherein the number of vertical pillars serve as transistors includes forming a number of vertical pillars having a storage density which is much greater than one bit for each 1.0 lithographic feature squared (1F²) unit area.
